(19) United States
(12) Patent Application Publication
(10) Pub. No.: US 2008/0220343 A1
(43) Pub. Date: Sep. 11, 2008

(54) Ink Composition and Method of Using the Same to Produce Color Filter

(75) Inventors: Chi-Sheng Chen, Hsin-Chu (TW); Lun Tsai, Hsin-Chu (TW); Wen-Bin Wu, Hsin-Chu (TW); Shen-Jye Shieh, Hsin-Chu (TW); Shu-Chin Lee, Hsin-Chu (TW); Feng-Yuan Gan, Hsin-Chu (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: AU Optronics Corporation, Hsin-Chu (TW)

(21) Appl. No.: 12/031,058

(22) Filed: Feb. 14, 2008

(30) Foreign Application Priority Data
Mar. 6, 2007 (TW) 96107655

(51) Int. Cl. G03F 1/00; C08K 5/05; C08K 5/053; C08K 5/13

(52) U.S. Cl. 430/7; 524/548; 524/556; 524/261; 524/379; 524/388; 524/330; 524/323

(57) ABSTRACT

An ink composition for producing a color filter is provided. The ink composition comprises a colorant, a binder and plural solvents. A color filter production method using the above-mentioned ink composition is also provided. The ink composition is adhered to the designated light transmitting regions on the surface of a transparent substrate. Then, the ink composition adhered to the designated light transmitting regions is solidified.

### RELATED APPLICATIONS

This application claims priority to Taiwan Application Serial Number 96107655, filed Mar. 6, 2007, which is herein incorporated by reference.

### BACKGROUND

1. Field of Invention

The present invention relates to an ink composition and manufacturing method of using the same. More particularly, the present invention relates to an ink composition and method of using the same to produce color filter.

2. Description of Related Art

Right after the rapid growth of semiconductor industry, display industry has also become one of the most important industries. Diversified electronic products have been commercialized to meet the variety of demands for personal use in this highly developed information society. Therefore, the demand of LCD, especially chromatic LCD, widely applied as the display of electronic products has been greatly increased. Color filter used for manufacturing chromatic LCD has therefore become an important device to allow colored images to be displayed, which means color filter quality has remarkable influence on the performance of the chromatic LCD.

One conventional method, pigment dispersed method, for manufacturing large sized color filter is to have pigment photoresist coated on a glass substrate, and then soft back, exposure, development and hard bake processes are performed to obtain red (R), green (G), and blue (B) pixels. As the required size of color filter is getting increased, conventional method for manufacturing color filter is getting far below the satisfactory level. Therefore, a new ink jet printing method has been developed to simplify manufacturing process, obtain large size coating, increase resolution and lower down manufacturing cost.

However, the application of conventional ink on ink jet printing may possibly lead to some problems such as nozzle clogging, ink leaking, satellite ink droplet, ink droplet surface hump and incomplete ink printing on ink droplet periphery, ink overflow and imprecise color mixing. Take nozzle clogging as an example, U.S. Pat. No. 6,627,364 discloses nozzle clogging can be reduced by adding solvent with boiling point higher than 245° C. into ink, but the selected solvent is usually either ether or alcohol with high surface tension, problems of ink droplet surface hump and incomplete ink printing on periphery of an ink droplet are therefore unavoidable after ink droplet has been solidified.

### SUMMARY

An aspect of the present invention is to provide an ink composition applied on ink jet printing technique for producing color filter. The use of the ink composition can prevent conventional ink jet printing problems such as nozzle clogging, ink leaking and satellite ink droplet, and a flat ink droplet surface can be obtained after the ink droplet has been solidified.

An ink composition and method of using the same to produce color filter is provided. The ink composition comprises colorant, binder, a first solvent and a second solvent. The boiling point of the first solvent under atmospheric pressure is 180-280° C., the surface tension of the first solvent at 25° C. is 25-32 dyne/cm. The boiling point of the second solvent is lower than that of the first solvent but the surface tension of the second solvent is higher than that of the first solvent.

### DETAILED DESCRIPTION

### Embodiments

An ink composition is provided to be applied to the ink jet printing technique for producing color filter. The ink composition comprises colorant, binder, a first solvent and a second solvent. The boiling point of the first solvent under atmospheric pressure is 180-280° C., the surface tension (σ₁) of the first solvent at 20° C. is 25-32 dyne/cm. The boiling point of the second solvent is lower than that of the first solvent but the surface tension (σ₂) of the second solvent is higher than that of the first solvent. According to one embodiment of the present invention, the ink composition comprises 20-95% by weight of the first solvent with respect to a total amount of the first solvent and the second solvent. According to another embodiment of the present invention, the boiling point of the second solvent under atmospheric pressure is 130-230° C. According to still another embodiment of the present invention, the surface tension of the second solvent is higher than that of the first solvent by about 2-10 dyne/cm (σ₂−σ₁).

According to one embodiment of the present invention, the above mentioned colorant can be organic pigment, inorganic pigment, or dye. According to another embodiment of the present invention, the colorant is thermal stable organic pigment to meet the thermal stability requirement of the color filter product and manufacturing process. In addition, according to yet another embodiment of the present invention, the colorant can be mixed with dispersant. The dispersant can be cationic, anionic, non-ionic, amphoteric, silicon-based, or fluorine-based surfactant.

According to one embodiment of the present invention, the above mentioned binder can be acrylic resin with carboxylic group or epoxy group. A monomer of the acrylic resin with carboxylic group may contain unsaturated carboxylic acid (e.g. acrylic acid, methacrylic acid, butenoic acid, or cinnamic acid), unsaturated dicarboxylic acid (e.g. maleic acid, fumaric acid, or itaconic acid), or anhydride (e.g. maleic anhydride, itaconic anhydride).

According to another embodiment of the present invention, the above mentioned unsaturated carboxylic monomer can also be mixed with unsaturated monomer without carboxylic group. The unsaturated monomer without carboxylic group can be aromatic vinyl compound, such as styrene, α-methyl styrene, o-vinyl toluene, m-vinyl toluene, p-vinyl toluene, p-chlorostyrene, o-methoxystyrene, m-methoxystyrene, p-methoxystyrene, o-vinylbenzyl methylether, m-vinylbenzyl methylether, p-vinylbenzyl methylether, o-vinylbenzyl glycidyl ether, m-vinylbenzyl glycidyl ether, p-vinylbenzyl glycidyl ether, or any combination thereof. According to one embodiment of the present invention, the above mentioned binder has molecular weight of 1,000-100,000, and preferably 1,500-20,000.

Several experiments were carried out in order to obtain the ink composition. Table 1 shows various solvents selected and the relevant boiling points and surface tension. Table 2 shows the various solvent combinations to be tested. Table 3 shows the results of experiments.

TABLE 1

| | | Boiling point under | |
|---|---|---|---|
| Solvent | | atmospheric pressure | Surface tension at |
| code | solvent | (° C.) | 20° C. (dyne/cm) |
| A | 1,3-butylene glycol | 232 | 31.2 |
| | diacetate | | |
| B | diethylene glycol | 245 | 30 |
| | monobutyl ether | | |
| | acetate | | |
| C | dipropylene glycol | 209 | 27.3 |
| | monomethyl ether | | |
| | acetate | | |
| D | diethylene glycol | 194 | 34.6 |
| | monomethyl ether | | |
| E | diethylene glycol | 202 | 31.8 |
| | monoethyl ether | | |
| F | triethylene glycol | 249 | 36.4 |
| | monomethyl ether | | |
| G | propylene glycol | 149 | 25.4 |
| | monopropyl ether | | |

TABLE 2

| | First solvent | | | | Second solvent | | | |
|---|---|---|---|---|---|---|---|---|
| | | boiling | | weight | | boiling | | weight |
| | Solvent | point | σ₁ | percentage | Solvent | point | σ₂ | percentage |
| Embodiment | code | (° C.) | (dyne/cm) | (%) | code | (° C.) | (dyne/cm) | (%) |
| 1 | A | 232 | 31.2 | 80 | D | 194 | 34.6 | 20 |
| 2 | B | 245 | 30 | 70 | E | 202 | 31.8 | 30 |
| 3 | C | 209 | 27.3 | 60 | D | 194 | 34.6 | 40 |

TABLE 3

| | | incomplete ink | ink droplet | |
|---|---|---|---|---|
| | Satellite ink | printing on ink droplet | surface | |
| Embodiment | droplet | periphery | hump | σ₂ − σ₁ |
| 1 | ◯ | ◯ | Δ | 3.4 |
| 2 | ◯ | ◯ | Δ | 1.8 |
| 3 | ◯ | ◯ | ◯ | 7.3 |

◯: none,
Δ: mild,
X: serious

Each embodiment was carried out by preparing ink with specific solvent ratio listed in Table 2, then the prepared ink was printed by piezoelectrical ink jet printing method on the designated light transmitting region of the transparent substrate. The glass substrate was heated up to 90° C. on a hot plate for 3 minutes and baked in an oven at 230° C. for 40 minutes. The transparent substrate was cooled down and the ink printed on the designated light transmitting region of the glass substrate was examined by microscope to understand the shape of printed ink, and was also examined by scanning probe roughness tester to understand the flatness of the printed ink.

Refer to embodiment 1 in Table 2, the first solvent contained in ink was 1,3-butylene glycol diacetate (boiling point under atmospheric pressure: 232° C., surface tension at 20° C.: 31.2 dyne/cm, weight percentage: 80%). The second solvent was diethylene glycol monomethyl ether (boiling point under atmospheric pressure: 194° C., surface tension at 20° C.: 34.6 dyne/cm, weight percentage: 20%). Investigation results of embodiment 1 in Table 3 indicate that solidified ink showed no satellite ink drop and no incomplete ink printing on ink droplet periphery, but mild ink droplet surface hump.

Refer to embodiment 2 in Table 2, the first solvent contained in ink was diethylene glycol monobutyl ether acetate (boiling point under atmospheric pressure: 245° C., surface tension at 20° C.: 30 dyne/cm, weight percentage: 70%). The second solvent was diethylene glycol monoethyl ether (boiling point under atmospheric pressure: 202° C., surface tension at 20° C.: 31.8 dyne/cm, weight percentage: 30%). Investigation results of embodiment 2 in Table 3 indicate that solidified ink showed no satellite ink drop and no incomplete ink printing on ink droplet periphery, but mild ink droplet surface hump.

Refer to embodiment 3 in Table 2, the first solvent contained in ink was dipropylene glycol monomethyl ether acetate (boiling point under atmospheric pressure: 209° C., surface tension at 20° C.: 27.3 dyne/cm, weight percentage: 60%). The second solvent was diethylene glycol monomethyl ether (boiling point under atmospheric pressure: 194° C., surface tension at 20° C.: 34.6 dyne/cm, weight percentage: 40%). Investigation results of embodiment 2 in Table 3 indicate that solidified ink showed no satellite ink drop and no incomplete ink printing on ink droplet periphery, and no ink droplet surface hump.

Refer to Table 2 and Table 3, overall comparative among embodiment 1, embodiment 2 and embodiment 3 suggests that when ink has been solidified, the second solvent with boiling point lower than the first solvent will be easily evaporated and then the first solvent will be left, the solidified ink shows no incomplete ink printing on ink droplet periphery and limited ink droplet surface hump if the solvent with higher boiling point has lower surface tension.

### Comparative Embodiments

In order to verify the conclusion obtained from the embodiments of the present invention, three comparative experiments have been carried out. Refer to Table 4 and Table 5, Table 4 shows various solvent percentages selected in the three comparative experiments. Table 5 shows the investigation results.

TABLE 4

| | First solvent | | | | Second solvent | | | |
|---|---|---|---|---|---|---|---|---|
| | | boiling | | Weight | | boiling | | Weight |
| Comparative | Solvent | point | σ₁ | percentage | Solvent | point | σ₂ | percentage |
| embodiment | code | (° C.) | (dyne/cm) | (%) | code | (° C.) | (dyne/cm) | (%) |
| 1 | F | 249 | 36.4 | 100 | — | — | — | — |
| 2 | F | 249 | 36.4 | 60 | G | 149 | 25.4 | 40 |
| 3 | C | 209 | 27.3 | 70 | G | 149 | 25.4 | 30 |

TABLE 5

| | | incomplete ink | | |
|---|---|---|---|---|
| Comparative | Satellite | printing on ink | ink droplet | |
| embodiment | ink droplet | droplet periphery | surface hump | σ2 − σ1 |
| 1 | ◯ | X | X | — |
| 2 | ◯ | X | X | −11 |
| 3 | Δ | ◯ | Δ | −1.9 |

◯: none,
Δ: mild,
X: serious

Refer to comparative embodiment 1 in Table 4, the ink composition comprised only one solvent which was triethylene glycol monomethyl ether (boiling point under atmospheric pressure: 249° C., surface tension at 20° C.: 36.4 dyne/cm, weight percentage: 100%).

Refer to comparative embodiment 2 in Table 4, the ink composition comprised 60% triethylene glycol monomethyl ether as the first solvent and 40% propylene glycol monopropyl ether as the second solvent. The boiling point of the first solvent (249° C.) is higher than the boiling point of the second solvent (149° C.) under atmospheric pressure, and the surface tension of the first solvent (36.4 dyne/cm) is higher than the surface of the second solvent (25.4 dyne/cm) at 20° C.

Refer to comparative embodiment 3 in Table 4, the ink composition comprised 70% dipropylene glycol monomethyl ether acetate as the first solvent and 30% propylene glycol monopropyl ether as the second solvent. The boiling point of the first solvent (209° C.) is higher than the boiling point of the second solvent (149° C.) under atmospheric pressure, and the surface tension of the first solvent (27.3 dyne/cm) is higher than the surface of the second solvent (25.4 dyne/cm) at 20° C.

Each of the above ink composition was also printed by piezoelectrical ink jet printing method on the designated light transmitting region of the glass substrate. The glass substrate was heated up to 90° C. on a hot plate for 3 minutes and baked in an oven at 230° C. for 40 minutes. The glass substrate was cooled down and the ink printed on the designated light-transmitting region of the glass substrate was examined by microscope to understand the shape of the printed ink, and was also examined by scanning probe roughness tester to understand the flatness of the printed ink. The investigation results of comparative embodiments are listed in Table 5.

Refer to the investigation results of the comparative embodiment 1 in Table 5, the investigation results of the comparative embodiment 1 show no satellite ink droplet but serious incomplete ink printing on ink droplet periphery and serious ink droplet surface hump. This suggests the ink composition with only one high boiling point and high surface tension (>32 dyne/cm) solvent leads to no satellite ink droplet, but serious incomplete ink printing on ink droplet periphery and serious ink droplet surface hump are inevitable.

Refer to the investigation results of the comparative embodiment 2 in Table 5, the first solvent in comparative embodiment 2 is the same as the first solvent in comparative embodiment 1 but a second solvent with lower boiling point is added to the ink composition of the embodiment 2. What is different from embodiments 1-3 is the surface tension of the second solvent is lower than the surface tension of the first solvent. The investigation results of the comparative embodiment 2 show no satellite ink droplet but serious incomplete ink printing on ink droplet periphery and serious ink droplet surface hump. This suggests when the ink composition comprises the first solvent with high boiling point and high surface tension, and the second solvent with low boiling point and low surface tension, the solidified ink has no satellite ink droplet because of sufficient surface tension but incomplete ink printing on ink droplet periphery and ink droplet surface hump are inevitable, if high boiling point solvent has too high surface tension.

Refer to the investigation results of the comparative embodiment 3 in Table 5, the first solvent with high boiling point and high surface tension in comparative embodiment 2 was replaced by dipropylene glycol monomethyl ether acetate with relatively low boiling point and low surface tension. Even though ink droplet surface hump is reduced, satellite ink droplet can be observed due to insufficient solvent surface tension.

The investigations of the above embodiments and comparative embodiments show that the second solvent with lower boiling point is easily evaporated so that the percentage of the first solvent is getting increased during the baking process. If the surface tension of the first solvent with high boiling point can be lower than the surface tension of the second solvent, and the surface tension of the first solvent is about 25-32 dyne/cm, satellite ink droplet can be avoided because of high surface tension of the second solvent. The first solvent with high boiling point allows smooth ink printing during ink jet printing process, and relatively flat ink surface can be obtained after ink has been solidified because of low surface tension of the first solvent.

### Other Embodiments

According to another embodiment of the present invention, a leveling agent is added to the ink composition for improving ink surface flatness. The leveling agent can be silicon-based surfactant surfactant or fluorine-based surfactant.

According to another embodiment of the present invention, a proper heat-induced free radical initiator can be added to improve ink solidification. The heat-induced free radical initiator can be, for example, 1,1′-azobis(cyclohexane-1-carbonitrile) or 2-phenylazo-4-methoxy-2,4-dimethyl-pentanenitrile.

According to another embodiment of the present invention, a proper heat-induced acid generator is added to the ink composition as a cationic polymerization initiator or a condensation reaction catalyst to improve cross-linking efficiency, and increase chemical and thermal resistance. The heat-induced acid generator can be, for example, triaryl sulfonium, diethyl phosphate, or ammonium salt.

According to another embodiment of the present invention, a proper acid-treated cross-linking agent is added to the ink composition to improve ink solidification by the cross-linking reaction catalyzed by acid during the ink baking process. The acid-treated cross-linking agent can be, for example, N,N,N,N,N,N-hexa(alkoxymethyl)melamine or N,N,N,N-tetra(alkoxymethyl)glycoluril.

According to another embodiment of the present invention, a proper adhesion promoter is added to the ink composition for improving adhesion between ink and inorganic material. The adhesion promoter can be, for example, vinyl trimethoxy silane, vinyl triethoxy silane, 3-aminopropyl triethoxy silane.

According to another embodiment of the present invention, a proper ink jet stabilizer is added to the ink composition, the ink jet stabilizer can be, for example, methanol, ethanol, isopropanol, n-butanol, and glycerol. The ink composition can comprise a small amount of ink jet stabilizer or even without stabilizer

According to another embodiment of the present invention, a proper anti-oxidant an be added to the ink composition, the anti-oxidant can be, for example, 2,6-di-tertiary butylphenol, or 2-2-thio-di(4-methyl-6-tertiary-butyl phenol).

Although the present invention has been described in considerable detail with reference to certain embodiments thereof, other embodiments are possible. Therefore, their spirit and scope of the appended claims should no be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. An ink composition for manufacturing a color filter, comprising:
a colorant;
a binder;
a first solvent, wherein the boiling point of the first solvent is about 180-280° C. under atmospheric pressure and the surface tension of the first solvent is about 25-32 dyne/cm at 20° C.; and
a second solvent, wherein the boiling point of the second solvent is lower than the boiling point of the first solvent, and the surface tension of the second solvent is higher than the surface tension of the first solvent.

2. The ink composition of claim 1, wherein the ink composition comprises about 20-95% by weight of the first solvent with respect to a total amount of the IS first solvent and the second solvent.

3. The ink composition of claim 1, wherein the first solvent comprises 1,3-butylene glycol diacetate, diethylene glycol monobutyl ether acetate, or dipropylene glycol monomethyl ether acetate.

4. The ink composition of claim 1, wherein the boiling point of the second solvent is about 130-230° C. under atmospheric pressure.

5. The ink composition of claim 1, wherein the surface tension of the second solvent at 20° C. is higher than that of the first solvent by about 2-10 dyne/cm.

6. The ink composition of claim 1, wherein the second solvent comprises diethylene glycol monomethyl ether or diethylene glycol monoethyl ether.

7. The ink composition of claim 1, wherein the colorant comprises organic pigment, inorganic pigment or dye.

8. The ink composition of claim 1, further comprising a dispersant mixed with the colorant, wherein the dispersant is cationic surfactant, anionic surfactant, non-ionic surfactant, amphoteric surfactant, silicon-based surfactant, or fluorine-based surfactant.

9. The ink composition of claim 1, wherein the binder is an (meth)acrylic resin with carboxylic group or epoxy group

10. The ink composition of claim 9, wherein the resin with carboxylic group comprises an unsaturated carboxylic acid monomer or an anhydride.

11. The ink composition of claim 1, wherein the averaged molecular weight of the binder is about 1,000-100,000.

12. The ink composition of claim 1, wherein the averaged molecular weight of the binder is about 1,500-20,000.

13. The ink composition of claim 1, further comprising a leveling agent, wherein the leveling agent comprises silicon-based surfactant or fluorine-based surfactant.

14. The ink composition of claim 1, further comprising a heat-induced free radical initiator, wherein the heat-induced free radical initiator comprises 1,1′-azobis(cyclohexane-1-carbonitrile) or 2-phenylazo-4-methoxy-2,4-dimethyl-pentanenitrile.

15. The ink composition of claim 1, further comprising a heat-induced acid generator, wherein the heat-induced acid generator comprises triaryl sulfonium, diethyl phosphate, or ammonium salt.

16. The ink composition of claim 1, further comprising an acid-treated cross-linking agent, wherein the acid-treated cross-linking agent comprises N,N,N,N,N,N-hexa(alkoxymethyl)melamine or N,N,N,N-tetra(alkoxymethyl) glycoluril.

17. The ink composition of claim 1, further comprising an adhesion promoter, wherein the adhesion promoter comprises vinyl trimethoxy silane, vinyl triethoxy silane, or 3-aminopropyl triethoxy silane.

18. The ink composition of claim 1, further comprising an ink jet stabilizer, wherein the ink jet stabilizer comprises methanol, ethanol, isopropanol, n-butanol, or glycerol.

19. The ink composition of claim 1, further comprising an anti-oxidant, wherein the anti-oxidant comprises 2,6-di-tertiary butylphenol or 2-2-thio-di(4-methyl-6-tertiary-butyl phenol).

20. A method for manufacturing a color filter, comprising:
adhering the ink composition of claim 1 on a plurality of light transmitting regions of a substrate by using ink jet printing; and
solidifying the ink composition.
